(19) United States
(12) Patent Application Publication
(10) Pub. No.: US 2008/0122038 A1
(43) Pub. Date: May 29, 2008

(54) GUARD RING STRUCTURE WITH METALLIC MATERIALS

(75) Inventor: Masahiro INOHARA, Fujisawa-shi (JP)

Correspondence Address: BANNER & WITCOFF, LTD., 1100 13th STREET, N.W., SUITE 1200, WASHINGTON, DC, 20005-4051, US

(73) Assignee: TOSHIBA AMERICA ELECTRONIC COMPONENTS, INC., Irvine, CA (US)

(21) Appl. No.: 11/532,243

(22) Filed: Sep. 15, 2006

(51) Int. Cl. H01L 23/00; H01L 21/76

(52) U.S. Cl. 257/620; 438/401; 257/E23.194; 257/E21.54

(57) ABSTRACT

A semiconductor device and a method for making the semiconductor device having a guard ring formed by a trench filled with a metallic material is described. Using the trench, crack and moisture propagation may be eliminated or prevented from propagating from a dicing area to an active circuit area of a chip.

### BACKGROUND

During the manufacturing process of semiconductor devices, the devices need to be separated from each other to form individual chips. The dicing procedure used to separate the chips from each other is well-known in the art. For instance, one may use a thin blade or grinder to score and/or separate the chips from each other. Due to inaccuracies or variations in the surface of the cutting blade, resulting cuts between semiconductor chips may be rough. The roughness of these cuts may lead to cracks and/or delaminations of the semiconductor layers. In some instances, this delamination and/or cracking of the semiconductor layers may lead to further separation of stacked films in the semiconductor chip and/or pathways for which moisture may enter the semiconductor chip.

To prevent cracks and/or pathways for moisture to enter the semiconductor chip, conventional processes have used multiple metal layers to form a guard ring around a semiconductor chip. FIGS. 1A and B show conventional guard ring structures. In FIG. 1A, four semiconductor chips are shown joined together, ready to be separated. Each of the four chips has an active area 10-13, a buffer region 14-17 surrounding the active area 10-13, a layered guard ring 18-21, and a dicing area 22-25 surrounding each of the layered guard rings 18-21.

FIG. 1B shows a cross-section of a layered guard ring 18-21 from FIG. 1A. Here, transistor and isolation layer 101 is formed on substrate 100. Next, dielectric capping layer 102 is formed on the transistor and isolation layer 101. Inter layer dielectric 108 is formed on dielectric capping layer 102. In this fashion, dielectric capping layer is 103 through 107 are formed with inter layer dielectrics 109-112 separating the dielectric capping layers. A layered guard ring is formed by the combination of metal layers 118-122 connected by metal plugs 113-117 to substrate 101. FIG. 1B shows the layered guard ring 18-21 with arrow 0129 pointing in the direction of the inside of the chip and arrow 130 pointing in the direction of the dicing areas 22-25.

One of the issues associated with a layered guard ring structure as shown in FIGS. 1A and 1B is that the layered guard rings do not adequately prevent crack propagation and/or moisture propagation from dicing areas 22-25 to the inside of the chips 129. For instance, the stress of dicing and/or subsequent handling or processing may result in the delamination of various layers or propagation of cracks as shown by directional arrows 131-132. Here, the cracks may propagate along to the surfaces of the various layers in both horizontal and vertical directions. The cracks between the metal components (namely, plugs 113-117 and layers 118-122) may in part be due to imperfect fusing between the components.

FIG. 2 shows an alternative approach to that of FIG. 1A. In FIG. 2, two layered guard rings are shown. The first includes metal plugs 213-217 and metal layers 223-227. The second includes metal plugs 218-222 and metal layers 228-232. Gear to also shows substrate 201, transistor and isolation layer 101, dielectric capping layers 202-207, and inter layer dielectric's 208-212. And issue again exists with the structure as shown in FIG. 2 in that cracks propagate along the layers.

FIG. 3 shows yet another approach to layered guard ring structures. Here, on substrate 301, transistor and isolation layer 101, dielectric capping layers 302-307 are formed with inter layer dielectric's 308-312. Layered guard ring includes plugs 313-317 and metal layers 318-322. FIG. 3 also includes an unfilled trench 328 that allows for reduced stress applied to the layered guard ring structure during the dicing process.

Another issue with the approaches of FIGS. 2 and 3 include the additional space required for the second guard ring structure and the unfilled trench, respectively. With respect to FIG. 2, the extra guard ring is formed by metal plugs 218-222 and metal layers 228-232. In FIG. 3, the extra guard ring is formed by the unfilled trench 328. With semiconductor real estate being expensive, these additional guard ring structures consume a real estate that could be put to better usage.

Accordingly, an improved structure is needed that addresses at least one of the issues described above.

### SUMMARY

This summary is provided to introduce a selection of concepts in a simplified form that are further described below in the Detailed Description. This summary is not intended to identify key features or essential features of the claimed subject matter

Aspects of the invention address one or more of the issues described above, thereby providing an improved guard ring structure for semiconductor chips.

These and other aspects of the disclosure will be apparent upon consideration of the following detailed description of illustrative embodiments.

### BRIEF DESCRIPTION OF THE DRAWINGS

The following provides descriptions of the various drawings.

FIGS. 1A and 2B show a conventional guard ring structure.

FIG. 2 shows another conventional guard ring structure using to layered guard rings.

FIG. 3 shows yet another conventional guard ring structure using a layered guard ring and trench.

FIG. 4 shows a guard ring comprising metallic materials in accordance with aspects of the present invention.

FIGS. 5A-5C show a process for forming the guard ring in accordance with aspects of the present invention.

FIG. 6 shows another guard ring comprising metallic materials in accordance with aspects of the present invention.

FIGS. 7A-7C show a process for forming the guard ring of FIG. 6 in accordance with aspects of the present invention.

FIG. 8 shows a liner used with the structure of FIG. 4 in accordance with aspects of the present invention.

FIG. 9 shows a liner used with the structure of FIG. 7C in accordance with aspects of the present invention.

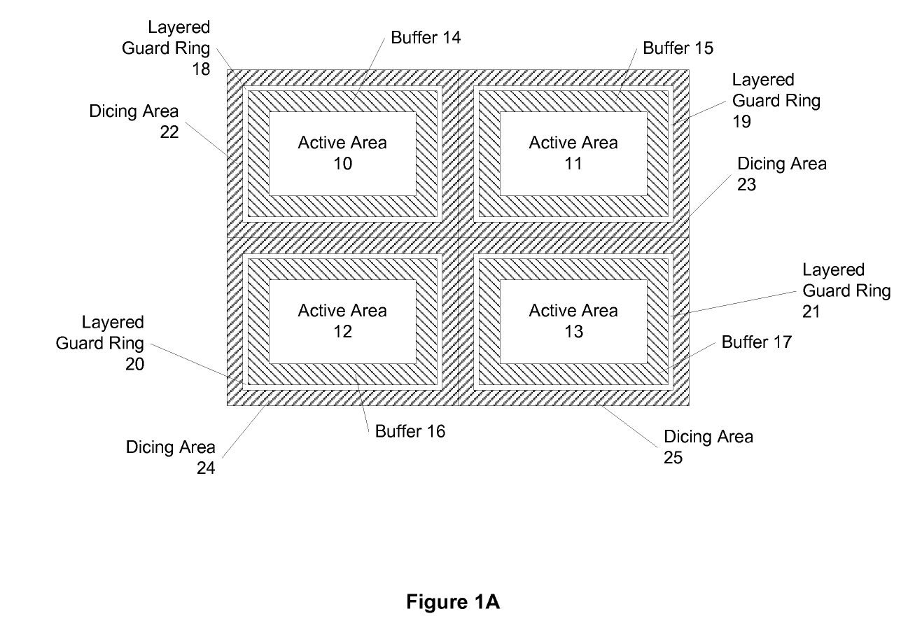

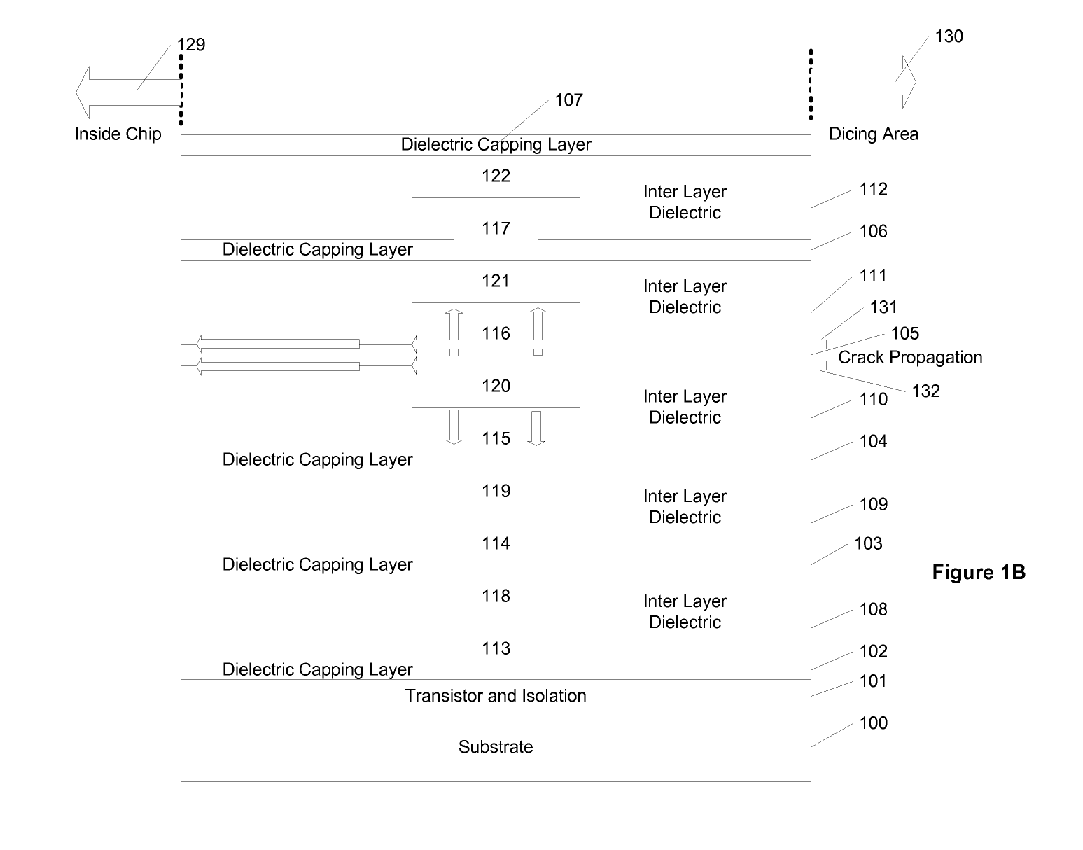

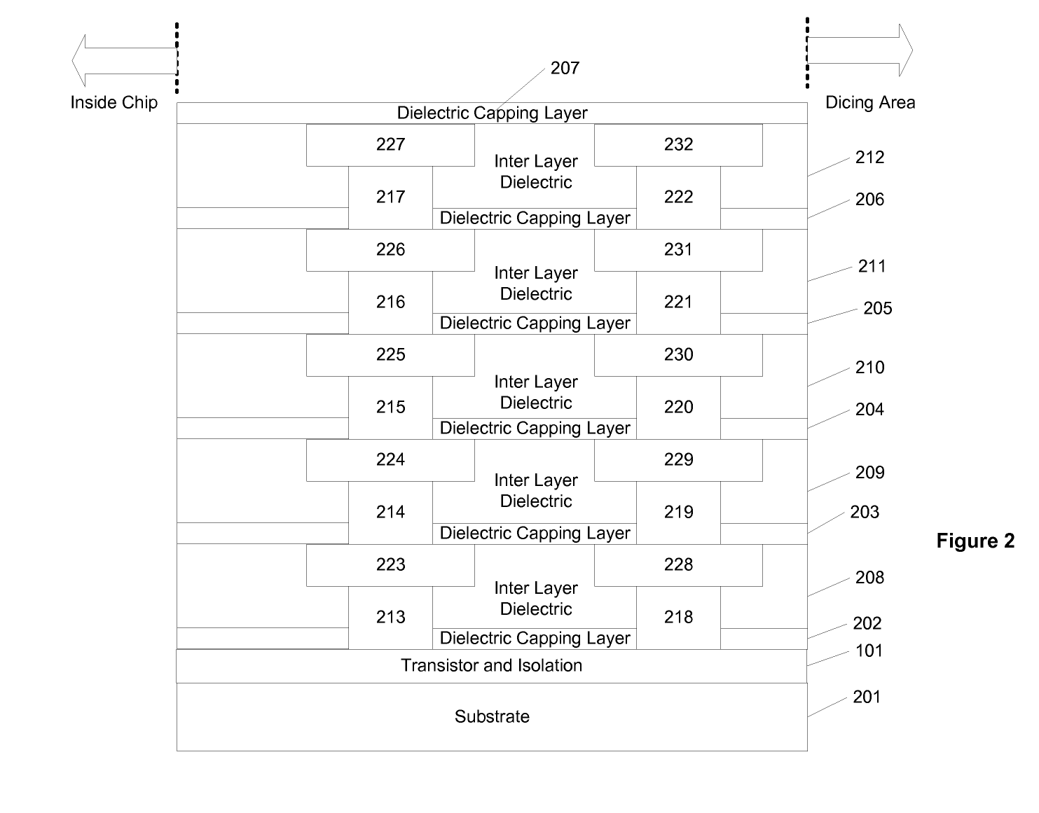

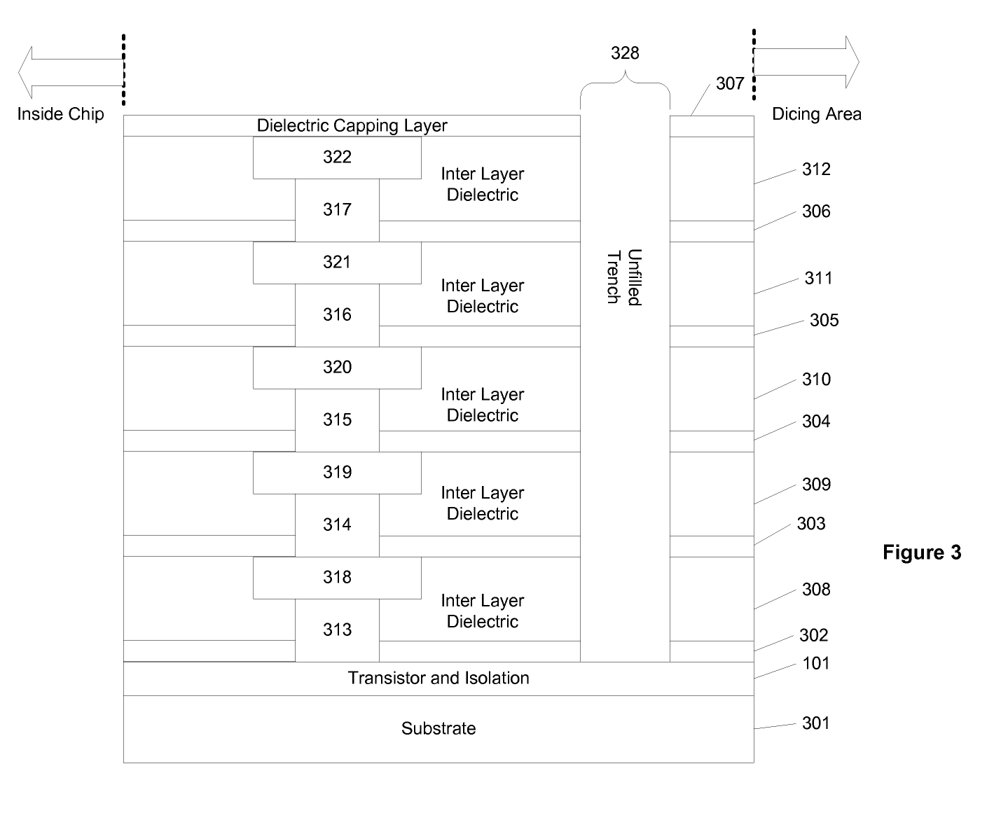

### DETAILED DESCRIPTION

Aspects of the present invention relates to a guard ring structure that prevents delamination and/or moisture from penetrating from the periphery of a chip after dicing.

The various aspects summarized previously may be embodied in various forms. The following description shows by way of illustration of various combinations and configurations in which the aspects may be practiced. It is understood that the described aspects and/or embodiments are merely examples, and that other aspects and/or embodiments may be utilized and structural and functional modifications may be made, without departing from the scope of the present disclosure.

It is noted that various connections are set forth between elements in the following description. It is noted that these connections in general and, unless specified otherwise, may be direct or indirect and that this specification is not intended to be limiting in this respect.

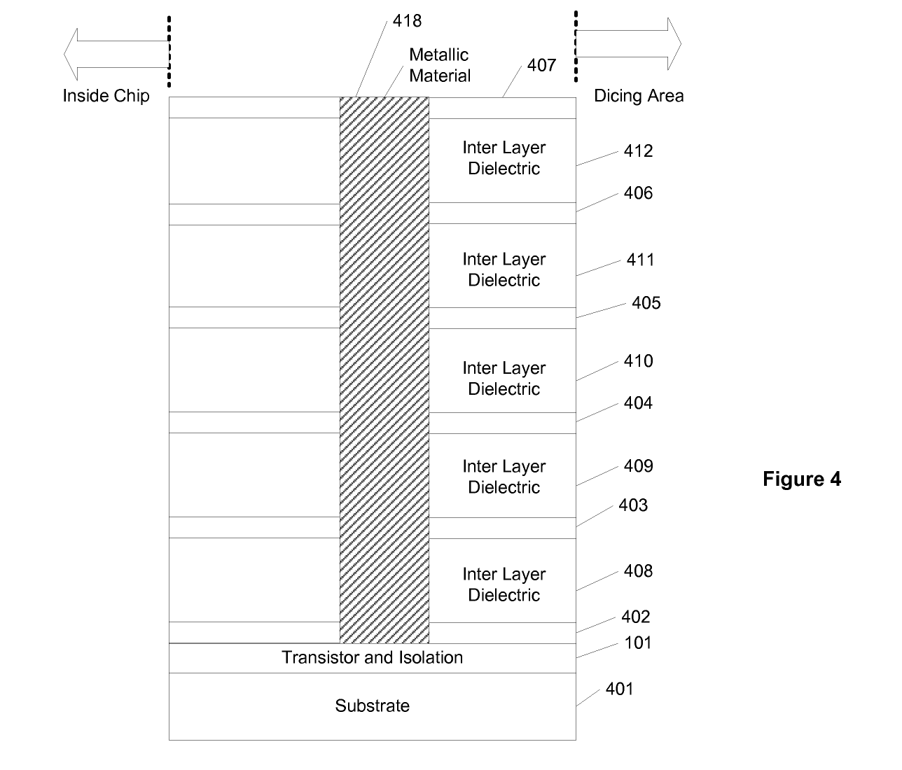

FIG. 4 shows a first embodiment in which a substrate 401 has a number of layers formed on it. The layers include transistor and isolation layer 101, dielectric capping layers of 402-407, and inter layer dielectrics 408-412. FIG. 4 also includes a trench filled with a metallic material or materials 418.

Here, the seamless nature of metallic materials 418 prevents crack or moisture propagation along layer lines. In particular, the guard ring structure does not have horizontal interfaces that may permit cracking or other failures. One benefit of the guard ring structure of FIG. 4 includes the elimination of placing an extra guard ring and/or extra trench outside of a regular guard ring.

The material filled in the trench of FIG. 4 may include one or more of solder, aluminum, copper, titanium, tantalum and tungsten. It is appreciated that other metals or metal-based products may be used as known in the art.

In one aspect of the present invention, the process of forming and filling the trench as shown in FIG. 4 may be a separate set of processes from the standard manufacture of the semiconductor chips. Alternatively, at least the filling of the trench may be performed in conjunction with other required processes for completing the chip. For instance, if the trench is to be filled with solder, the filling process may be performed in conjunction with solder plating for solder bump fabrication (also known as C4).

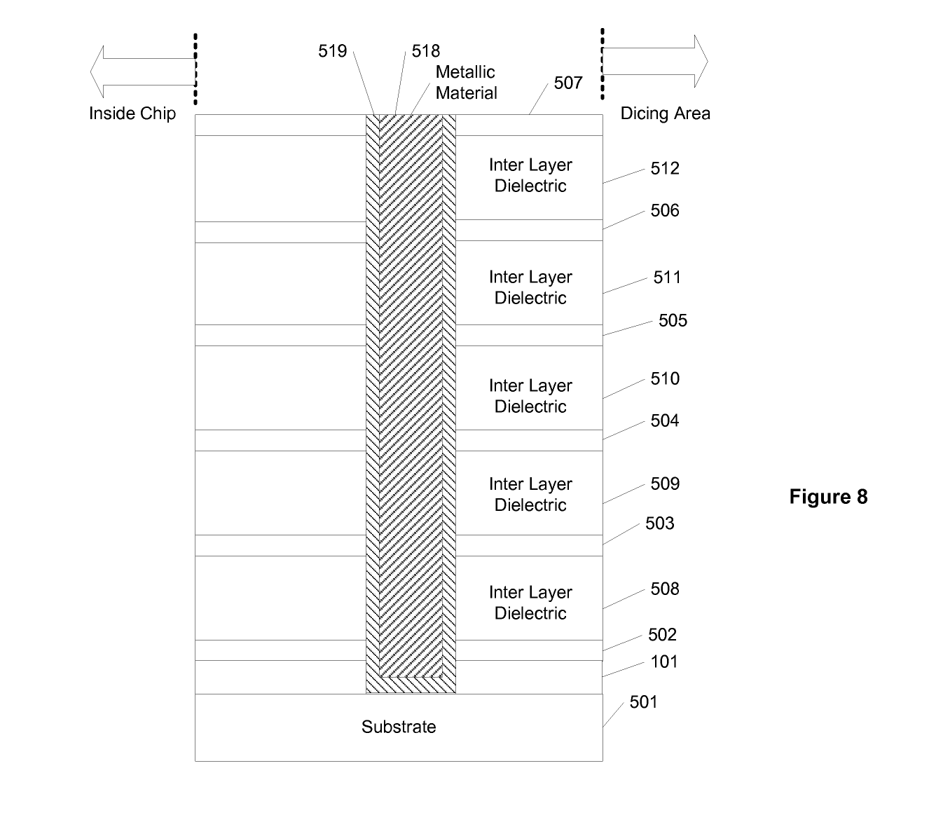

Further, some trench materials may need a liner. For instance, the use of tungsten may require the use of a liner as the tungsten is deposited by a CVD (chemical vapor deposition) process. FIG. 8 shows an example of a liner used in combination with the embodiment of FIG. 4. Here, liner 519 may be used to isolate the material that is used in trench 518. Alternatively, the liner may not need to be used if using a different process to deposit tungsten (or any other material that generally requires a liner), for instance via PVD.

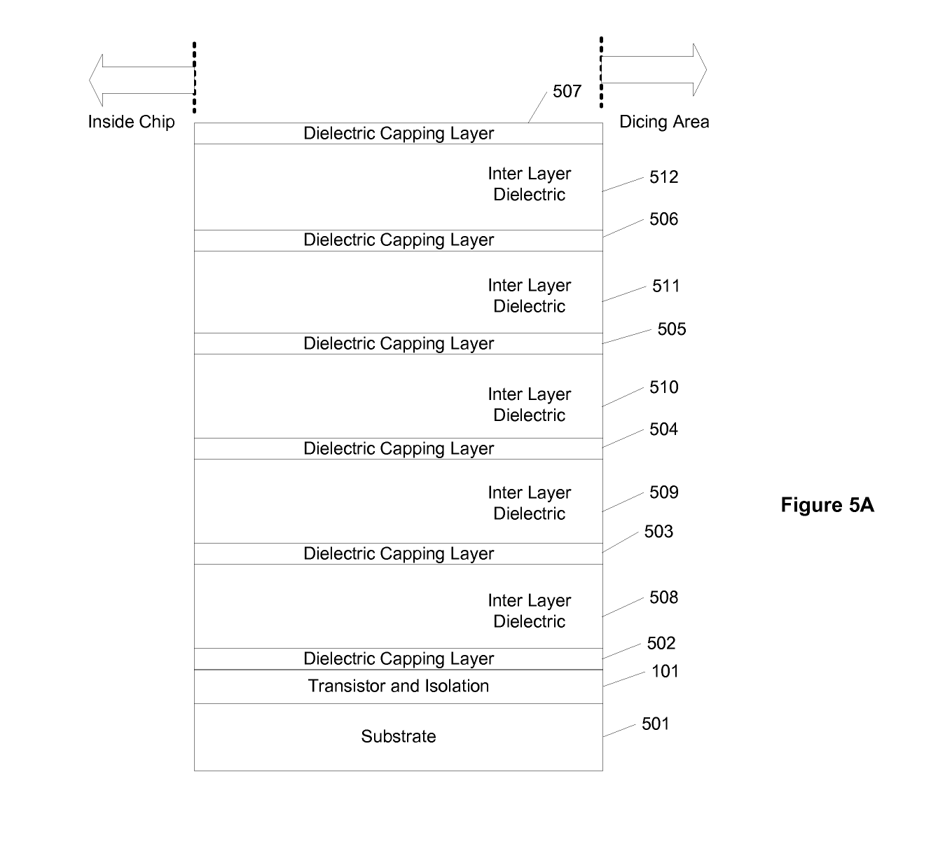

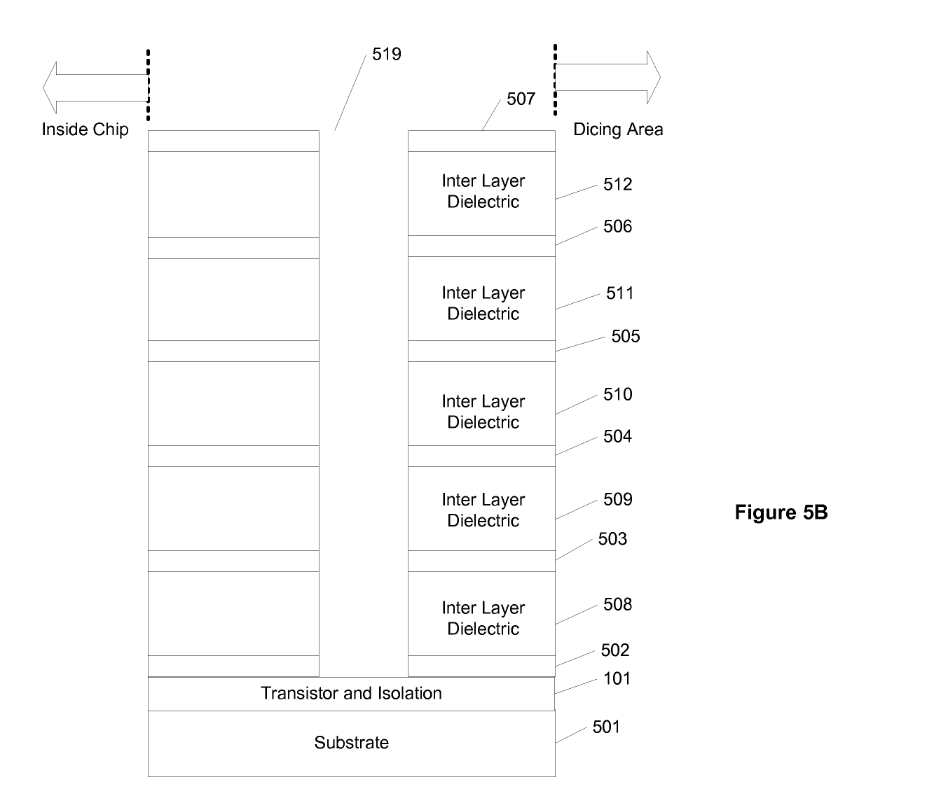

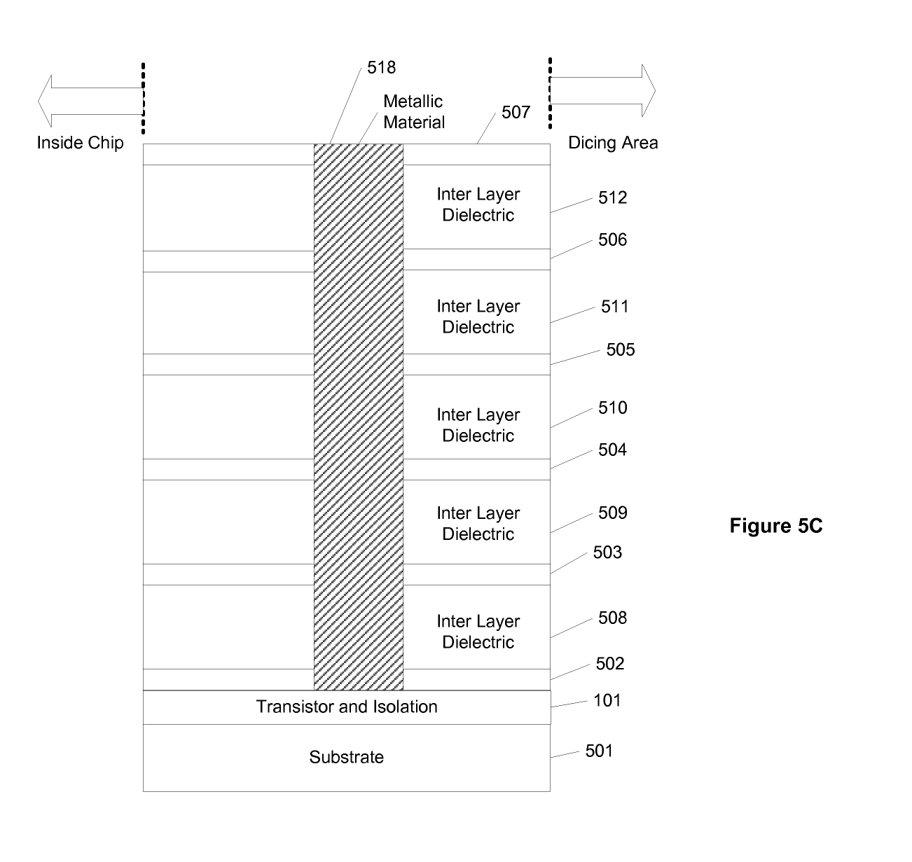

FIGS. 5A-5C show a process for forming the filled trench of FIG. 4. Here, FIG. 5A includes the elements of FIG. 4 with no trench. In particular, FIG. 5A includes a substrate 501, transistor and isolation layer 101, dielectric capping layers 502-507, and inter layer dielectrics 508-512.

FIG. 5B the structure of FIG. 5A with trench 519 formed in the chip. Trench 519 may be formed by a number of known processes including, but not limited to, RIE etching and other and isotropic etching processes. In FIG. 5C, the etching of trench 519 is performed until the trench reaches substrate 501.

FIG. 5C shows a filling process in which a metallic material or materials 518 fill trench 519. Here again, known filling techniques may be used.

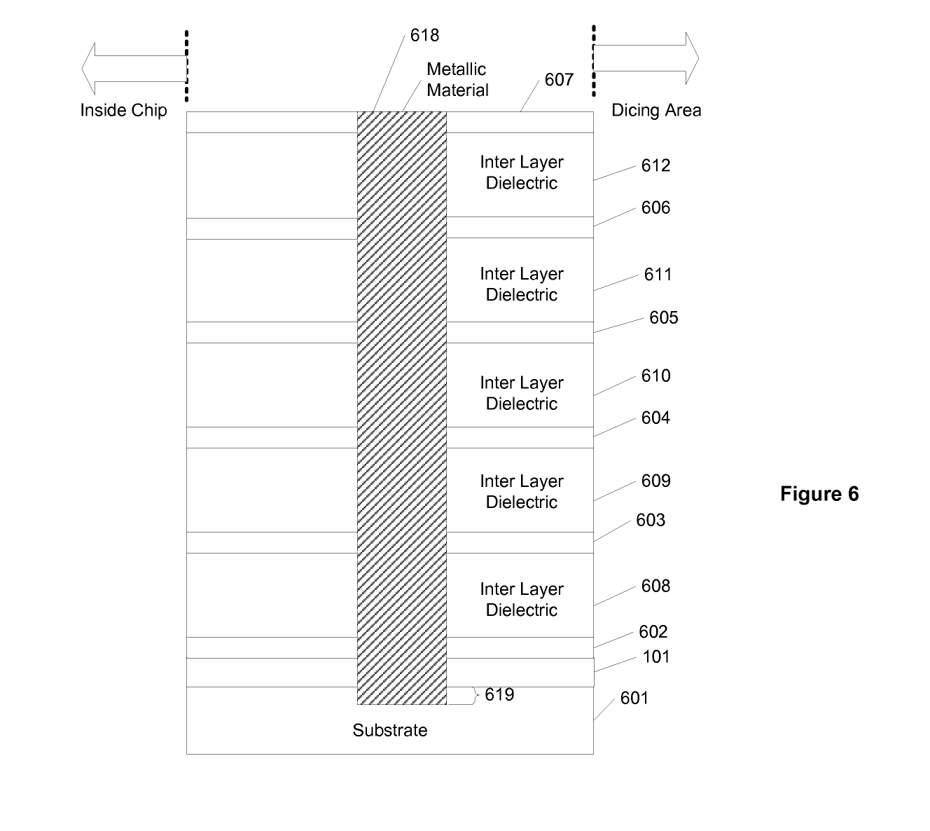

FIG. 6 shows an alternative embodiment of the present invention. Here, substrate 601 has formed on it transistor and isolation layer 101, dielectric capping layers 602-607, and inter layer dielectrics 608-612. FIG. 6 also includes a trench filled with a metallic material or materials 618, where the bottom of the trench extends (619) below the top surface of substrate 601.

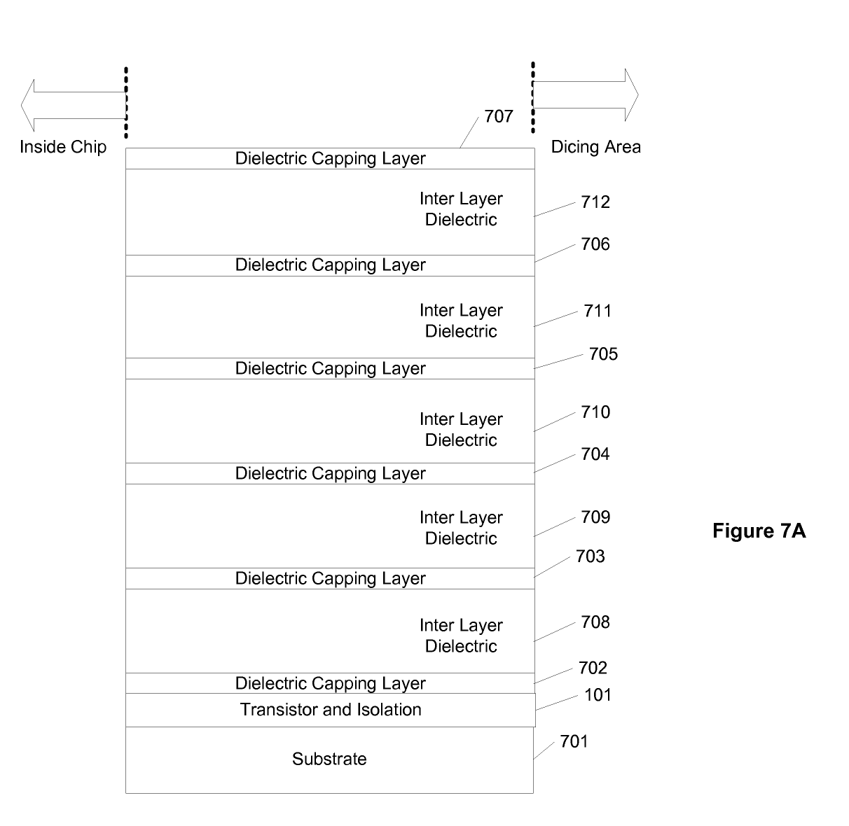

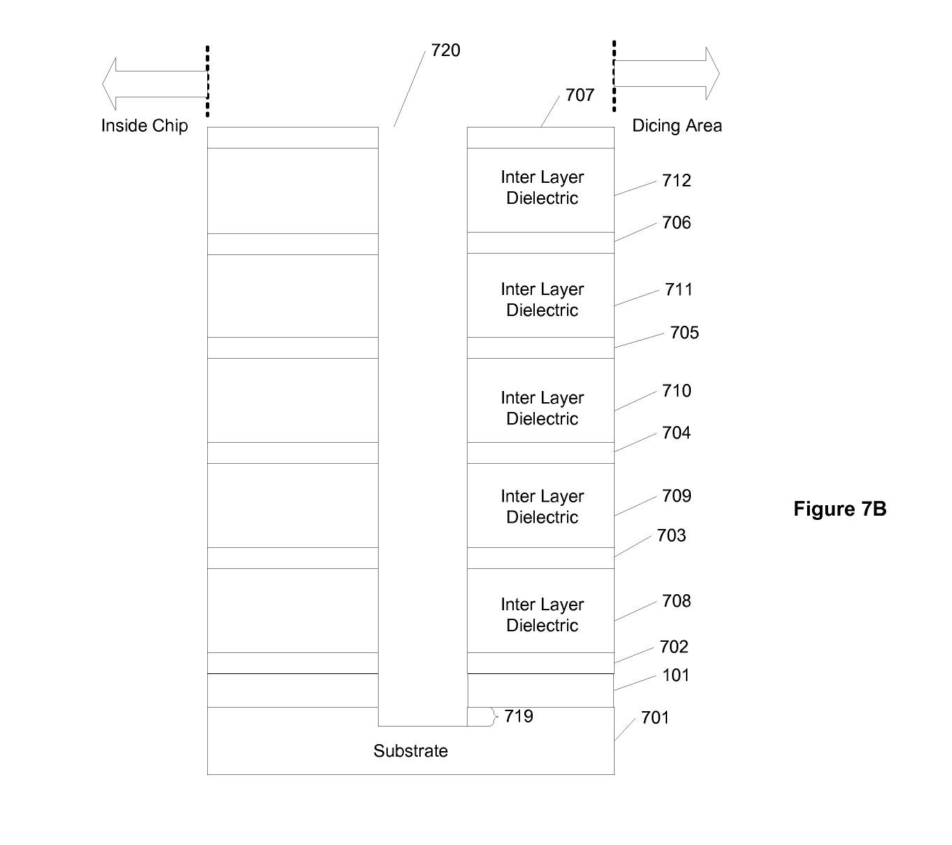

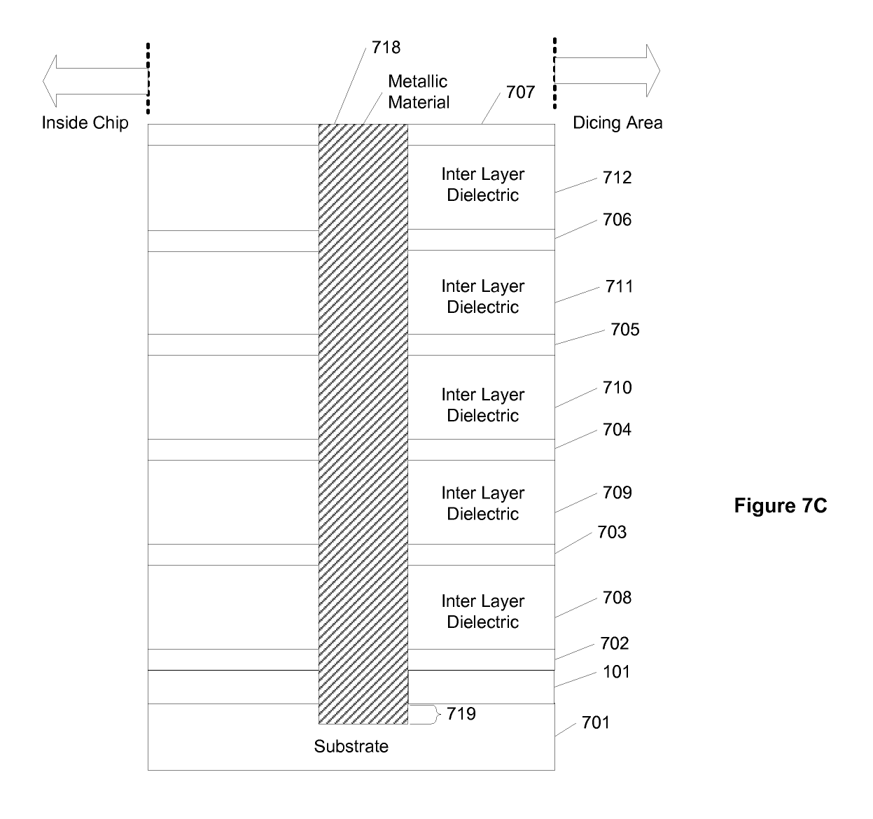

FIGS. 7A-7C show a process for forming the guard ring of FIG. 6. As shown in FIG. 7A, substrate 701 has formed on it transistor and isolation layer 101, dielectric capping layers 702-707, and inter layer dielectrics 708-712. In FIG. 7B, a trench 720 is formed that passes through the top surface of substrate 701 by distance 719. Trench 720 may be formed by known and isotropic etching techniques including, but not limited to, reactive ion etching (RIE) and other etching techniques. Finally, a metallic material or metallic materials 718 are filled in trench 720. As trench 720 extends by distance 719 and to substrate 701, crack propagation along the surfaces of dielectric capping layers and the substrate 701 may be prevented.

For instance, distance 719 may be greater than or equal to 0.1 μm.

Substrate 701 may be a solid substrate with a singular doping profile, may have various layers through which distance 719 passes, or may be another combination type of substrate including but not limited to silicon-on-insulator (SOI) and the like. For SOI type structures, the trench may extend through an initial substrate and into an insulating layer or further down.

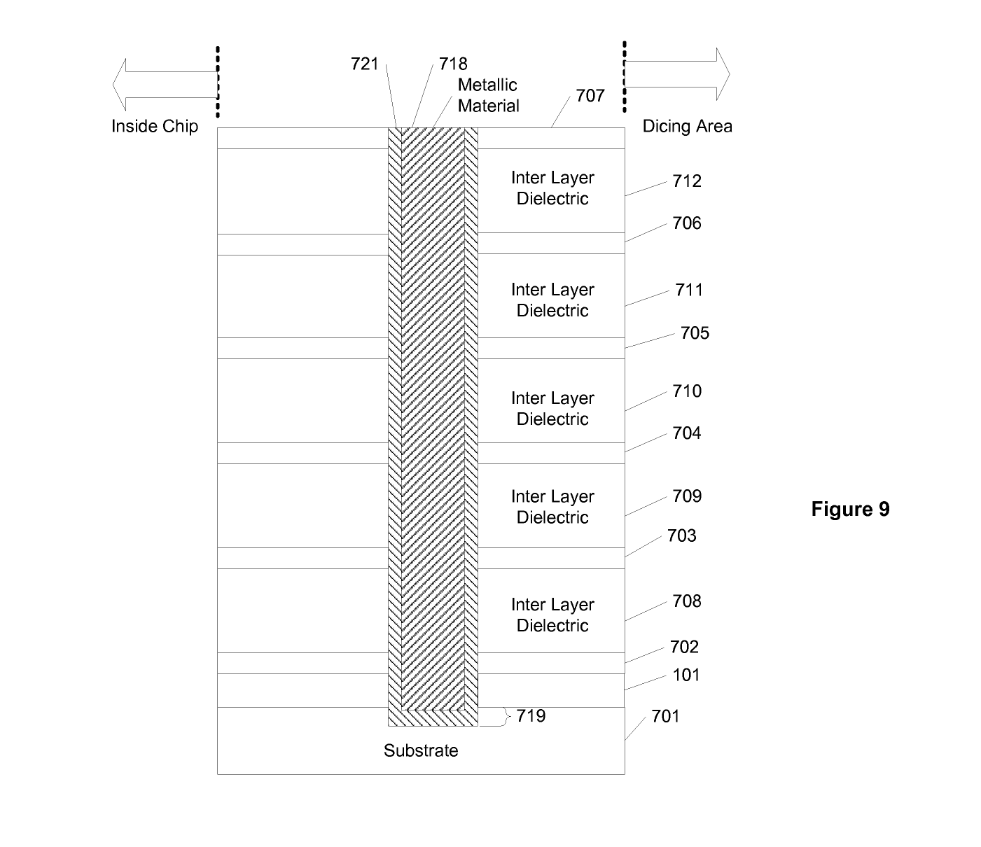

FIG. 9 shows an example of the use of a liner material 721 in the trench having material 718. Here, the liner may be used in conjunction with, for example, tungsten deposited by a CVD process.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims. Numerous other embodiments, modifications and variations within the scope and spirit of the appended claims will occur to persons of ordinary skill in the art from a review of this disclosure.

I claim:

1. A semiconductor device comprising:
an active circuit area;
a dicing area; and
a trench formed between said active circuit area and said dicing area, said trench being filled with a metallic material.

2. The semiconductor device according to claim 1, said trench only including said a metallic material.

3. The semiconductor device according to claim 1, said trench also including a liner material, said liner material located between walls of said trench and said metallic material.

4. The semiconductor device according to claim 1, wherein said trench extends to a surface of a substrate of said semiconductor device.

5. The semiconductor device according to claim 1, wherein said trench extends below a surface of said semiconductor device.

6. The semiconductor device according to claim 1, further comprising:
dielectric capping layers formed on a substrate, said dielectric capping layers are separated by inter layer dielectrics.

7. The semiconductor device according to claim 1, further comprising:
a liner in said trench.

8. The semiconductor device according to claim 1, wherein said trench forms a guard ring around said active circuit area.

9. A process for forming a semiconductor device comprising the steps of:
forming circuit layers and inter layer dielectric layers on a substrate, wherein at least part of said circuit layers and said interlayer dielectric layers are formed within an active circuit area of said semiconductor device;
forming a trench outside of said active area; and
filling said trench with a metallic material.

10. The process according to claim 9, further comprising the steps of:
forming caps on said circuit layers during said forming said circuit layers and inter layer dielectric layers step.

11. The process according to claim 9, further comprising the steps of:
forming a liner within said trench prior to filling said trench with said metallic material.

12. The process according to claim 9, wherein said forming said trench step forms said trench to a top surface of said substrate.

13. The process according to claim 9, wherein said forming said trench step forms said trench below a top surface of said substrate.

14. The process according to claim 9, wherein said filling step fills said trench with at least one of solder, aluminum, copper, titanium, tantalum and tungsten.

15. The semiconductor device according to claim 1, wherein said trench is filled with at least one of solder, aluminum, copper, titanium, tantalum and tungsten.
